(19) United States
(12) Patent Application Publication
(10) Pub. No.: US 2013/0187122 A1
(43) Pub. Date: Jul. 25, 2013

(54) PHOTONIC DEVICE HAVING EMBEDDED NANO-SCALE STRUCTURES

(71) Applicants: Yea-Chen Lee, Zhubei City (TW); Jung-Gang Chu, Zhunan Township (TW); Ching-Hua Chiu, Hsinchu City (TW); Hung-Wen Huang, Hsinchu City (TW)

(72) Inventors: Yea-Chen Lee, Zhubei City (TW); Jung-Gang Chu, Zhunan Township (TW); Ching-Hua Chiu, Hsinchu City (TW); Hung-Wen Huang, Hsinchu City (TW)

(73) Assignee: TAIWAN SEMICONDUTOR MANUFACTURING COMPANY, LTD., Hsin-Chu (TW)

(21) Appl. No.: 13/354,162

(22) Filed: Jan. 19, 2012

(51) Int. Cl. H01L 33/04; H01L 33/60

(52) U.S. Cl. 257/9; 438/29; 257/E33.06; 257/E33.008

(57) ABSTRACT

The present disclosure involves a method of fabricating a lighting apparatus. The method includes forming a first III-V group compound layer over a substrate. The first III-V group compound layer has a first type of conductivity. A multiple quantum well (MQW) layer is formed over the first III-V group compound layer. A second III-V group compound layer is then formed over the MQW layer. The second III-V group compound layer has a second type of conductivity different from the first type of conductivity. Thereafter, a plurality of conductive components is formed over the second III-V group compound layer. A light-reflective layer is then formed over the second III-V group compound layer and over the conductive components. The conductive components each have better adhesive and electrical conduction properties than the light-reflective layer.

### TECHNICAL FIELD

The present disclosure relates generally to semiconductor fabrication, and more particularly, to fabrication of semiconductor light-emitting devices.

### BACKGROUND

An LED device, as used herein, is a semiconductor light source for generating a light at a specified wavelength or a range of wavelengths. LED devices are traditionally used for indicator lamps, and are increasingly used for displays. An LED device emits light when a voltage is applied across a p-n junction formed by oppositely doped semiconductor compound layers. Different wavelengths of light can be generated using different materials by varying the bandgaps of the semiconductor layers and by fabricating an active layer within the p-n junction.

Traditionally, LEDs are made by growing a plurality of light-emitting structures on a growth substrate. The light-emitting structures along with the underlying growth substrate are separated into individual LED dies. At some point before or after the separation, electrodes or conductive pads are added to the each of the LED dies to allow the conduction of electricity across the structure. The light-emitting structure and the wafer on which the light-emitting structure is formed is referred to herein as an epi wafer. LED dies are then packaged by adding a package substrate, optional phosphor material, and optics such as lens and reflectors to become an optical emitter.

LED devices may be formed with different structures. For example, some of the LED structures include vertical LED structures and flip-chip LED structures. Theses structures may offer benefits such as better thermal management, reduced current crowding, or packaging efficiency. Conventional vertical or flip-chip LED structures may employ a reflective layer to redirect a light path. However, conventional vertical or flip-chip LED structures may suffer from drawbacks due to weak adhesion and poor Ohmic contact properties of the reflective layer.

Therefore, while existing methods of manufacturing the LED devices have been generally adequate for their intended purposes, they have not been entirely satisfactory in every aspect. Methods and designs that improve the adhesive and Ohmic contact properties of the reflective layer for vertical or flip-chip LED structures continue to be sought.

### BRIEF DESCRIPTION OF THE DRAWINGS

Aspects of the present disclosure are best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIGS. 1-7 are diagrammatic fragmentary cross cross-sectional side views of example LED structures according to various aspects of the present disclosure.

FIG. 8 is a flowchart illustrating a method of fabricating an LED device according to various aspects of the present disclosure.

### SUMMARY

One of the broader forms of the present disclosure involves a method of fabricating a photonic device. The method includes: forming a first doped semiconductor layer over a substrate; forming a quantum-well layer over the first doped semiconductor layer; forming a second doped semiconductor layer over the quantum-well layer, the first and second doped semiconductor layers being oppositely doped; forming a patterned mask layer over the second doped semiconductor layer; forming a conductive layer over the second doped semiconductor layer and over the patterned mask layer; and removing the patterned mask layer, thereby removing portions of the conductive layer formed directly on the patterned mask layer, wherein a plurality of Ohmic contact components are formed by remaining portions of the conductive layer disposed on the second doped semiconductor layer after the removing the patterned mask layer; and forming a reflective layer over the second doped semiconductor layer and over the Ohmic contact components.

In some embodiments, the first doped semiconductor layer and the second doped semiconductor layer each include a III-V family material.

In some embodiments, the III-V family material includes gallium nitride.

In some embodiments, the Ohmic contact components each include: Nickel, Titanium, Aluminum, Platinum, Palladium, Indium, Tin, or alloys thereof.

In some embodiments, the Ohmic contact components each have a thickness in a range from about 3 Angstroms to about 20 Angstroms.

In some embodiments, one of the first and second doped semiconductor layers is a n-type doped, and the other one of the first and second doped semiconductor layers is p-type doped.

In some embodiments, the Ohmic contact components have a periodic distribution.

In some embodiments, the reflective layer includes Aluminum, Silver, or alloys thereof.

In some embodiments, the Ohmic contact components occupy a percentage of total chip surface area, the percentage being in a range from about 0.5% to about 20%.

In some embodiments, the method further includes: forming a bonding metal layer over the reflective layer; and bonding a substrate to the photonic device through the bonding metal layer.

Another one of the broader forms of the present disclosure involves a method of fabricating a lighting apparatus. The method includes: forming a first III-V group compound layer over a substrate, wherein the first III-V group compound layer has a first type of conductivity; forming a multiple quantum well (MQW) layer over the first III-V group compound layer; forming a second III-V group compound layer over the MQW layer, wherein the second III-V group compound layer has a second type of conductivity different from the first type of conductivity; forming a plurality of conductive components over the second III-V group compound layer; and forming a light-reflective layer over the second III-V group compound layer and over the conductive components; wherein the conductive components each have better adhesive and electrical conduction properties than the light-reflective layer.

In some embodiments, the first III-V group compound layer and the second III-V group compound layer each include a gallium nitride material.

In some embodiments, the conductive components each include at least one of: Nickel, Titanium, Aluminum, Platinum, Palladium, Indium, Tin, and combinations thereof.

In some embodiments, the light-reflective layer includes at least one of: Aluminum, Silver, and alloys thereof.

In some embodiments, the conductive components each have a thickness no greater than about 20 Angstroms or up to about 50 Angstroms; and the reflective layer has a thickness that is greater than about 1000 Angstroms.

In some embodiments, the conductive components are formed at least in part by forming a patterned mask layer having a periodic distribution.

Still another one of the broader forms of the present disclosure involves a photonic device. The photonic device includes: a first doped semiconductor layer disposed over a substrate; a quantum-well layer disposed over the first doped semiconductor layer; a second doped semiconductor layer disposed over the quantum-well layer, the first and second doped semiconductor layers being oppositely doped; a plurality of nano-scale structures disposed over the second doped semiconductor layer; and a reflective layer disposed over the second doped semiconductor layer and over the nano-scale structures; wherein the first doped semiconductor layer and the second doped semiconductor layer each include a III-V family material; and the nano-scale structures are substantially thinner than the reflective layer.

In some embodiments, the nano-scale structures each include: Nickel, Titanium, Aluminum, Platinum, Palladium, Indium, Tin, or alloys thereof.

In some embodiments, the nano-scale structures have a periodic distribution and are about fifty times thinner than the reflective layer.

In some embodiments, the photonic device includes a flip-chip light-emitting diode (LED) structure or a vertical LED structure.

### DETAILED DESCRIPTION

It is understood that the following disclosure provides many different embodiments, or examples, for implementing different features of various embodiments. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. Moreover, the terms “top,” “bottom,” “under,” “over,” and the like are used for convenience and are not meant to limit the scope of embodiments to any particular orientation. Various features may also be arbitrarily drawn in different scales for the sake of simplicity and clarity. In addition, the present disclosure may repeat reference numerals and/or letters in the various examples. This repetition is for the purpose of simplicity and clarity and does not in itself necessarily dictate a relationship between the various embodiments and/or configurations discussed.

Semiconductor devices can be used to make photonic devices, such as light-emitting diode (LED) devices. When turned on, LED devices may emit radiation such as different colors of light in a visible spectrum, as well as radiation with ultraviolet or infrared wavelengths. Compared to traditional light sources (e.g., incandescent light bulbs), LED devices offer advantages such as smaller size, lower energy consumption, longer lifetime, variety of available colors, and greater durability and reliability. These advantages, as well as advancements in LED fabrication technologies that have made LED devices cheaper and more robust, have added to the growing popularity of LED devices in recent years.

Nevertheless, existing LED fabrication technologies may face certain shortcomings. One such shortcoming is that for LED devices having a conventional vertical structure or flip-chip structure, a reflective layer formed therein may have weak adhesion and poor Ohmic contact properties, which may degrade the performance of LED devices.

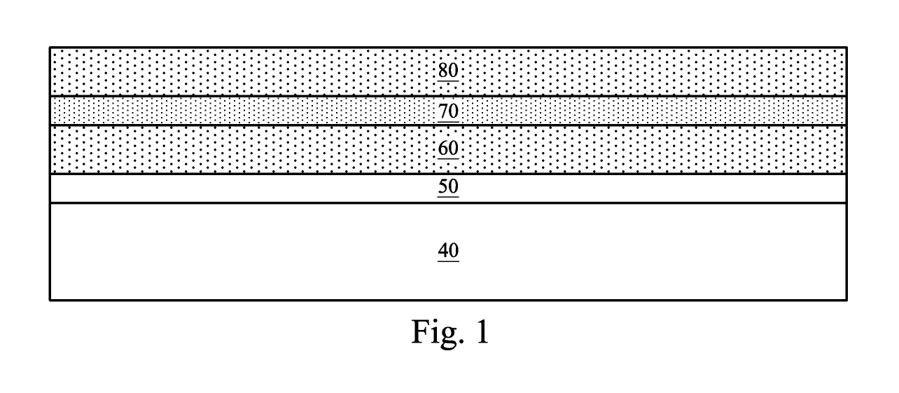

According to various aspects of the present disclosure, described below is a photonic device and a method of fabrication thereof that substantially overcomes the weak adhesion and poor Ohmic contact issues. The photonic device is an LED device in the embodiments discussed below. In more detail, FIGS. 1 to 7 are diagrammatic fragmentary cross-sectional side views and top views of a portion of an LED device at various fabrication stages. It is understood that FIGS. 1 to 7 have been simplified for a better understanding of the inventive concepts of the present disclosure. Accordingly, it should be noted that additional processes may be provided before, during, and after the method illustrated in FIGS. 1-7, and that some other processes may only be briefly described herein.

Referring to FIG. 1, a substrate 40 is provided. The substrate 40 is a portion of a wafer. In one embodiment, the substrate 40 includes a sapphire material. In other embodiments, the substrate 40 may include a different material, such as silicon carbide (SiC), bulk gallium nitride (GaN), silicon, or a suitable composite material. In an embodiment, the substrate 40 has a thickness that is in a range from about 200 microns (um) to about 1000 um.

An undoped semiconductor layer 50 is formed over the substrate 40. The undoped semiconductor layer 50 is free of a p-type dopant or an n-type dopant. In an embodiment, the undoped semiconductor layer 50 includes a compound that contains an element from a “III” family (or group) of the periodic table, and another element from a “V” family (or group) of the periodic table. For example, the III family elements may include Boron, Aluminum, Gallium, Indium, and Titanium, and the V family elements may include Nitrogen, Phosphorous, Arsenic, Antimony, and Bismuth. In the present embodiment, the undoped semiconductor layer 50 includes an undoped gallium nitride (GaN) material.

The undoped semiconductor layer 50 serves as a buffer layer (for example, to reduce stress) between the substrate 40 and layers that will be formed over the undoped semiconductor layer 50. To effectively carry out its function as a buffer layer, the undoped semiconductor layer 50 has reduced dislocation defects and good lattice structure quality. In an embodiment, the undoped semiconductor layer 50 has a thickness that is in a range from about 1.5 um to about 3.0 um.

A doped semiconductor layer 60 is formed over the undoped semiconductor layer 50. The doped semiconductor layer 60 is formed by an epitaxial growth process known in the art. In an embodiment, the doped semiconductor layer 60 is doped with an n-type dopant, for example Carbon (C) or Silicon (Si). In alternative embodiments, the doped semiconductor layer 60 may be doped with a p-type dopant, for example Magnesium (Mg). The doped semiconductor layer 60 includes a III-V group compound, which is gallium nitride compound in the present embodiment. Thus, the doped semiconductor layer 60 may also be referred to as a doped gallium nitride layer. In an embodiment, the doped semiconductor layer 60 has a thickness that is in a range from about 2 um to about 4 um.

A multiple quantum well (MQW) layer 70 is formed over the doped semiconductor layer 60. The MQW layer 70 includes alternating (or periodic) layers of active material, such as gallium nitride and indium gallium nitride (InGaN). For example, the MQW layer 70 may include a number of gallium nitride layers and a number of indium gallium nitride layers, wherein the gallium nitride layers and the indium gallium nitride layers are formed in an alternating or periodic manner. In one embodiment, the MQW layer 70 includes ten layers of gallium nitride and ten layers of indium gallium nitride, where an indium gallium nitride layer is formed on a gallium nitride layer, and another gallium nitride layer is formed on the indium gallium nitride layer, and so on and so forth. The light emission efficiency depends on the number of layers of alternating layers and thicknesses. In an embodiment, the MQW layer 70 has a thickness in a range from about 90 nanometers (nm) to about 200 nm. The actives layers of the MQW layer 70 may be formed by an epitaxial growth process known in the art.

It is understood that a pre-strained layer may optionally be formed between the doped semiconductor layer 60 and the MQW layer 70. The pre-strained layer may be doped with an n-type dopant such as Silicon. The pre-strained layer may serve to release strain and reduce a quantum-confined Stark effect (QCSE)—describing the effect of an external electric field upon the light absorption spectrum of a quantum well—in the MQW layer 70. The pre-strained layer may have a thickness in a range from about 30 nm to about 80 nm.

It is also understood that an electron blocking layer may optionally be formed over the MQW layer 70. The electron blocking layer helps confine electron-hole carrier recombination within the MQW layer 70, which may improve quantum efficiency of the MQW layer 70 and reduce radiation in undesired bandwidths. In an embodiment, the electron blocking layer may include a doped aluminum gallium nitride (AlGaN) material, and the dopant includes Magnesium. The electron blocking layer may have a thickness in a range from about 15 nm to about 20 nm. For the sake of simplicity, neither the pre-strained layer nor the electron blocking layer is illustrated herein.

A doped semiconductor layer 80 is formed over the MQW layer 70. The doped semiconductor layer 80 is formed by an epitaxial growth process known in the art. In an embodiment, the doped semiconductor layer 80 is doped with a dopant having an opposite type of conductivity from that of the doped semiconductor layer 60. Thus, in the embodiment where the doped semiconductor layer 60 is doped with an n-type dopant, the doped semiconductor layer 80 is doped with a p-type dopant, and vice versa. The doped semiconductor layer 80 includes a III-V group compound, which is a gallium nitride compound in the present embodiment. Thus, the doped semiconductor layer 80 may also be referred to as a doped gallium nitride layer. In an embodiment, the doped semiconductor layer 80 has a thickness that is in a range from about 150 nm to about 200 nm.

After the completion of the epitaxial growth process, an LED is created by the disposition of the MQW layer between the doped layers. When an electrical voltage (or electrical charge) is applied to the doped layers of the LED, the MQW layer emits radiation such as light. The color of the light emitted by the MQW layer corresponds to the wavelength of the radiation. The radiation may be visible, such as blue light, or invisible, such as ultraviolet (UV) light. The wavelength of the light (and hence the color of the light) may be tuned by varying the composition and structure of the materials that make up the MQW layer.

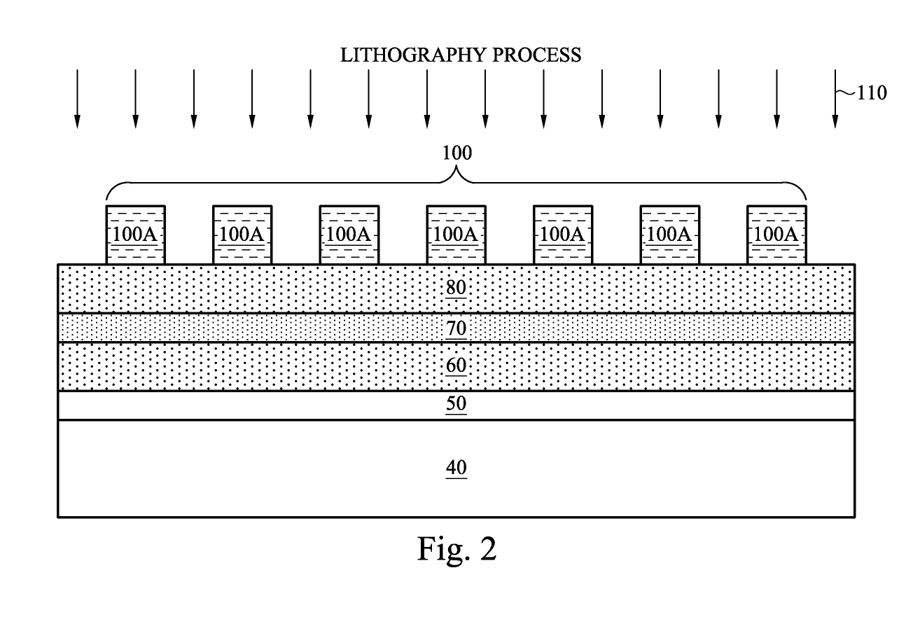

Referring now to FIG. 2, a patterned photoresist layer 100 is formed on the doped semiconductor layer 80. The pattern photoresist layer 100 is formed by depositing a photoresist material on the doped semiconductor layer 80 and thereafter patterning the photoresist material with a lithography process 110. The lithography process 110 includes one or more exposing, developing, baking, rinsing, and etching processes (not necessarily performed in that order). The performance of the lithography process 110 patterns the photoresist material into a plurality of photoresist segments 100A separated by openings. In an embodiment, the lithography process 110 is tuned in a manner such that the photoresist segments 100A are periodically distributed. In other words, the separation distances (the lateral dimension of the openings) separating adjacent photoresist segments 100A are the same throughout the patterned photoresist layer 100.

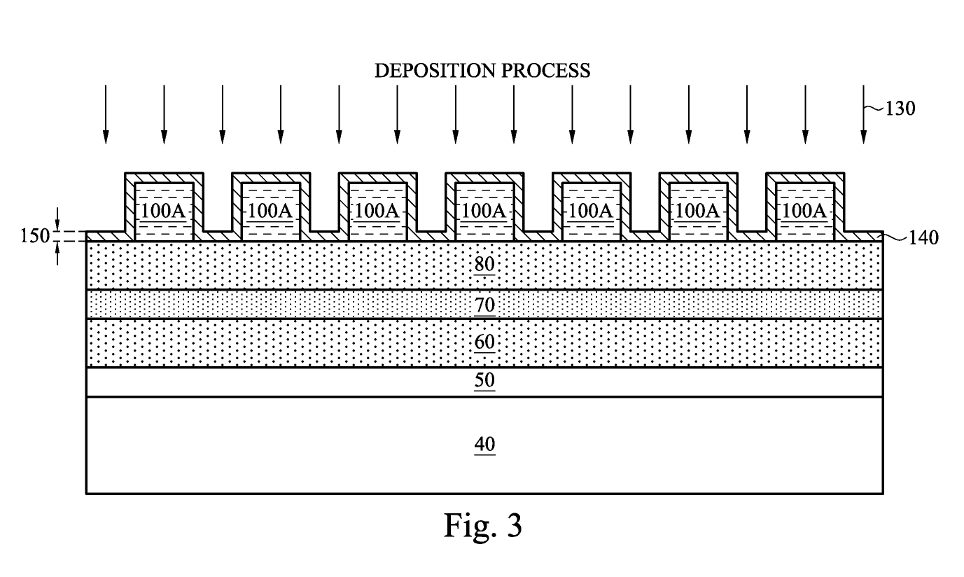

Referring now to FIG. 3, a chemical treatment process may be performed on the exposed surfaces of the doped semiconductor layer 80. The chemical treatment process involves using ACE (acetone) and IPA (isopropanol) material to remove surface organic contamination. The wafer is immersed in both chemicals for about 5 minutes and then rinsed by de-ionized water. Thereafter, the wafer is immersed in diluted HCl (about 30%) for about 5 minutes and then rinsed by de-ionized water. The chemical treatment process enhances Ohmic contact properties of the doped semiconductor layer 80. Thereafter, a deposition process 130 is performed to form a thin conductive layer 140 over the patterned photoresist layer 100 and over the doped semiconductor layer 80. In one embodiment, the deposition process 130 includes a thermal physical vapor deposition (PVD) process, which may also be referred to as an evaporation deposition process. In other embodiments, the deposition process 130 may include an atomic layer deposition (ALD) process, a chemical vapor deposition (CVD) process, an electron-gun (E-gun) process, a sputtering process, or combinations thereof.

The thin conductive layer 140 contains a material that is more adhesive and has better Ohmic contact properties than a reflective layer that will be formed over the thin conductive layer 140 in a later stage, as discussed below. The material of the thin conductive layer 140 does not react with the reflective layer that will be formed thereon. In an embodiment, the thin conductive layer 140 includes a metal material. The metal material may include at least one of Nickel (Ni), Titanium (Ti), Aluminum (Al), Platinum (Pt), Palladium (Pd), Indium (In), Tin (Sn), and alloys or combinations thereof. The thin conductive layer 140 has a thickness 150. In an embodiment, the thickness 150 is less than about 20 Angstroms, for example in a range from about 3 Angstroms to about 20 Angstroms, or less than about 50 Angstroms, for example in a range form about 3 Angstroms to about 50 Angstroms.

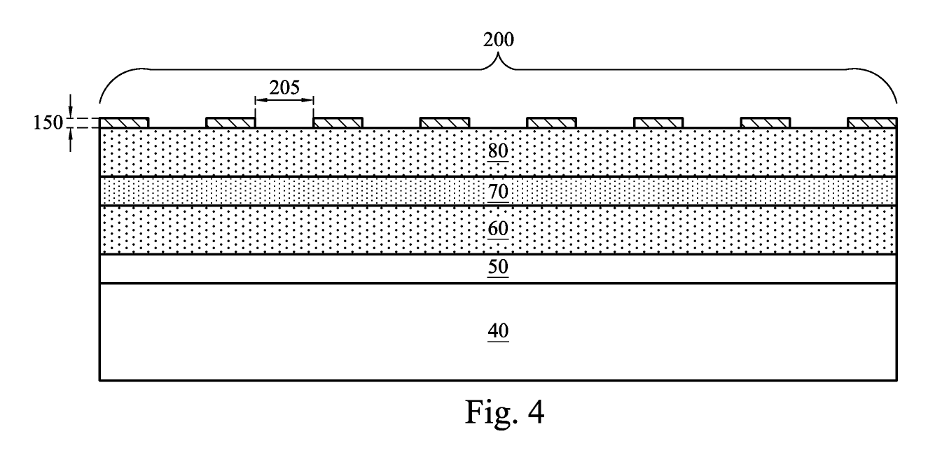

Referring now to FIG. 4, a metal lift-off process is performed to remove the patterned photoresist layer 100 (the photoresist segments 100A) and portions of the thin conductive layer 140 formed thereon. In an embodiment, the metal lift-off process includes a photoresist stripping process. As a result of the metal lift-off process, the remaining portions of the thin conductive layer 140 (portions disposed in between the photoresist segments 100A) form a plurality of nano-scale structures 200. The nano-scale structures 200 each retain the thickness 150 of the thin conductive layer 140.

The nano-scale structures 200 occupy only a portion of a chip surface area (for example a total surface area of the doped semiconductor layer 80). In an embodiment, a ratio between a total surface area of the nano-scale structures 200 and the total chip surface area is in a range from about 0.5% to about 20%. Stated differently, the amount of surface area (measured horizontally in the illustrated embodiment) occupied by the total number of the nano-scale structures with respect to the doped semiconductor layer 80 is greater than about 0.5%, but less than about 20%. From a top view (not illustrated), the nano-scale structures 200 may each have a circular or a polygonal shape, and may have a lateral dimension (e.g., a diameter of a circle) that is in a range from about 0.1 um to about 10 um. Each of the nano-scale structures 200 is spaced apart from adjacent nano-scale structures by a distance 205. In an embodiment, the spacing distance 205 is in a range from about 0.5 um to about 50 um. Also, it is understood that since the photoresist segments 100A may be periodically distributed in certain embodiments, the nano-scale structures 200 may also be periodically distributed in those embodiments.

It is also understood that the nano-scale structures 200 may be formed by an etch back process, instead of the metal lift off process discussed above. In the etch back process, a thin conductive layer similar to the thin conductive layer 140 is formed on the doped semiconductor layer 80, a patterned mask layer (e.g., hard mask) having opens is formed on the thin conductive layer, and etching (e.g., dry etching) is performed through openings of the patterned mask layer to remove portions of the thin conductive layer exposed by the openings. The nano-scale structures 200 are formed by portions of the thin conductive layer 140 remaining after the etch back process is performed.

Because the nano-scale structures 200 is thin and occupies only a small portion of a chip surface area, the nano-scale structures 200 is substantially non-absorptive of radiation that emits from the LED. In other words, little or no loss, for example, less than 5% or 1%, of radiation emitted by an LED occurs as the radiation passes through the nano-scale structures 200.

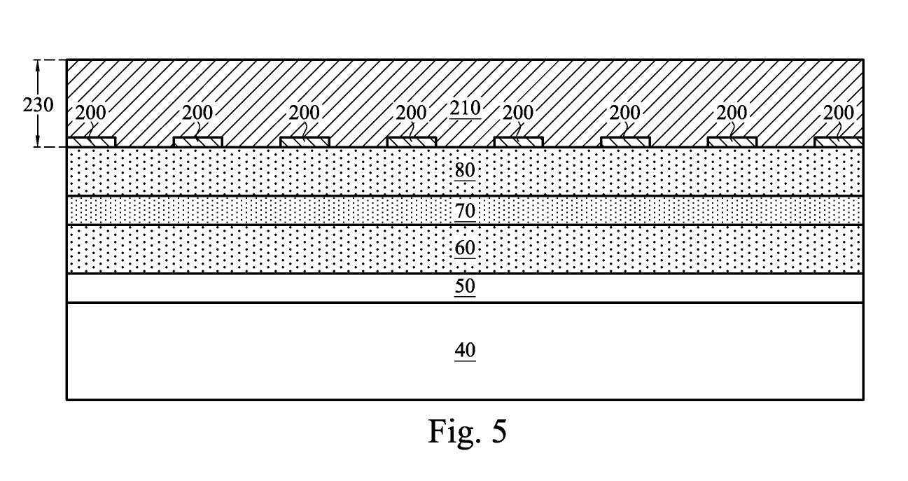

Referring now to FIG. 5, a reflective layer 210 is formed over the nano-scale structures 200 and over the doped semiconductor layer 80. The reflective layer 210 may be formed by a suitable deposition process known in the art, for example CVD, PVD, ALD, or combinations thereof. The reflective layer 210 is operable to reflect light, for example light emitted by the MQW layer 70. Thus, light emitted by the MQW layer 70 will be reflected by the reflective layer 210 back toward the MQW layer 70. In an embodiment, the reflective layer 210 includes a metal material such as Silver (Ag), Aluminum, or an alloy thereof. It is understood, however, that the reflective layer 210 has a different material composition than that of the nano-scale structures 200. For example, in an embodiment where the reflective layer 210 includes Aluminum, the nano-scale structures 200 are free of Aluminum. The reflective layer 210 has a thickness 230. In an embodiment, the thickness 230 is greater than about 1000 Angstroms. Since the nano-scale structures 200 are no greater than 20 nm, the reflective layer 210 is at least fifty times thicker than the nano-scale structures 200. The nano-scale structures 200 may be considered “embedded” within the reflective layer 210.

The implementation of the nano-scale structures 200 according to the embodiments disclosed herein offers advantages over existing LED structures. It is understood, however, that not all advantages are necessarily discussed herein, and different embodiments may offer additional advantages, and that no particular advantage is required for all embodiments.

One advantage is that the materials of the nano-scale structures 200 have better adhesive properties than the materials of the reflective layer 210. Consequently, the nano-scale structures 200 have good adhesion to the doped semiconductor layer 80 and to the reflective layer 210. Furthermore, the adhesion between the nano-scale structures 200 and the reflective layer 210 is further increased due to a greater surface contact area between the nano-scale structures 200 and the reflective layer 210 (compared to the surface contact area between the doped semiconductor layer 80 and the reflective layer 210). For these reasons, the adhesion between the doped semiconductor layer 80 and the reflective layer 210 is also increased as a result. The increased adhesion between layers of the LED structure disclosed herein reduces defects related to peeling issues. In addition, the nano-scale structures 200 offer enhanced mechanical strength as well, which further improves the integrity of the LED structure disclosed herein. Furthermore, the periodic distribution of the nano-scale structures 200 in certain embodiments help prevent adhesion non-uniformity issues.

Another advantage offered by the embodiments disclosed herein is that the nano-scale structures 200 have better Ohmic contact properties than the reflective layer 210. An ideal Ohmic contact is defined as a portion of a semiconductor device having a linear and symmetric current-voltage (I-V) curve. In other words, the Ohmic contact behaves like an ideal resistor. In the embodiments disclosed herein, the better Ohmic contact properties of the nano-scale structures 200 means that the nano-scale structures 200 behave more similarly to ideal resistors than the reflective layer 210. Due to the better Ohmic contact properties, a greater portion of the electrical current may flow through the nano-scale structures 200 (as opposed to through the reflective layer 210). Compared to traditional LED structures where the nano-scale structures 200 are absent, the LED structure disclosed herein has superior and more efficient performance.

Yet another advantage offered by the embodiments disclosed herein is that, since the nano-scale structures 200 are non-absorptive with respect to incoming light, they will not reduce the total amount of reflected light. In embodiments where the nano-scale structures 200 are reflective themselves, the help reflect and scatter incoming light, which may increase light output efficiency.

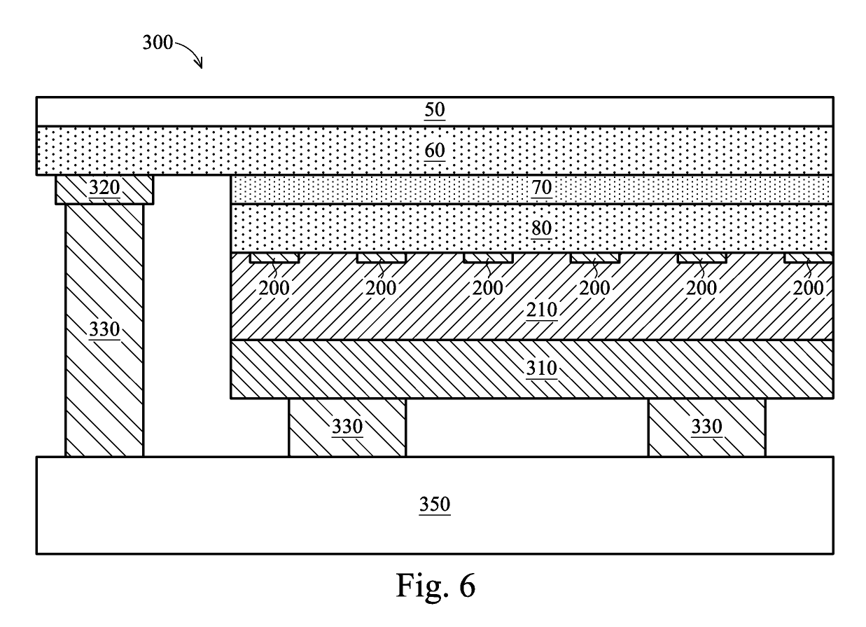

Additional LED fabrication processes may be performed to form a suitable LED device. FIG. 6 illustrates a diagrammatic cross-sectional side view of a flip-chip LED device 300 (or LED device having a flip-chip structure) formed according to the various aspects of the present disclosure. The flip-chip LED device 300 contains the various layers and components 40-210 shown in FIG. 5 and discussed above, except that they are shown to be in a vertically “flipped” configuration.

A bonding and barrier metal layer 310 is formed on the reflective layer 210. In an embodiment, the bonding and barrier metal layer 310 contains a barrier metal such as Ti, Pt, W, Ni, Pd, or ITO, and a bonding metal such as Au, Sn, Zn, In, Ag, or ITO. A portion of the layers 70, 80, 210 and 310 are etched to expose a portion of a surface of the doped semiconductor layer 60. A metal pad 320 is formed on the exposed surface of the doped semiconductor layer 60. In an embodiment, the metal pad 320 contains Cr, Ti, Al, In, Pd, or ITO. Thereafter, metal bumps 330 are formed on the bonding and barrier metal layer 310 and on the metal pad 320, respectively. In an embodiment, the metal bumps 330 contain Au or AuSn.

A substrate 350 is bonded to the layers 40-310 of the LED device through the metal bumps 330. In an embodiment, the substrate 350 contains a silicon material and may also be referred to as a silicon sub-mount 350. The substrate 40 may then be removed. To complete the fabrication of the flip-chip LED device 300, additional processes such as dicing, packaging, and testing processes may also be performed, but they are not illustrated herein for the sake of simplicity.

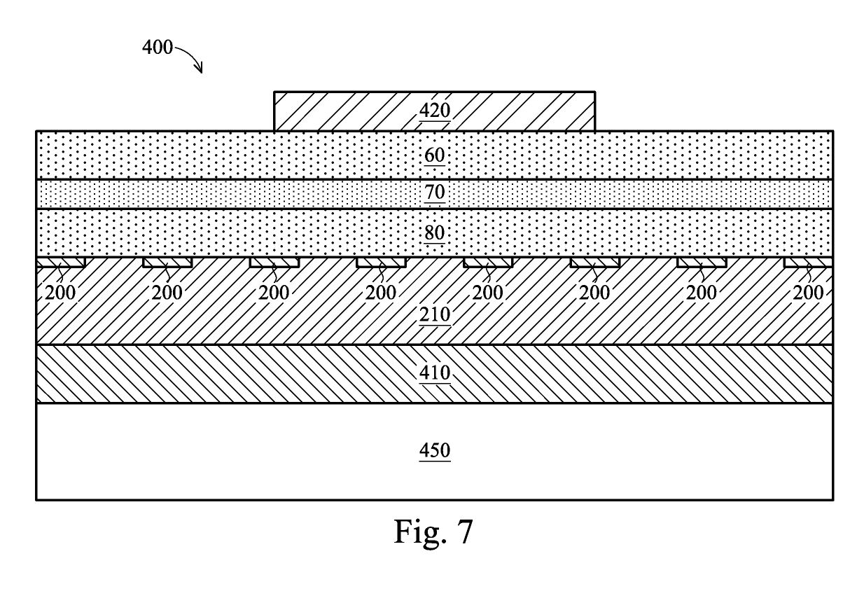

FIG. 7 illustrates a diagrammatic cross-sectional side view of a vertical LED device 400 (or LED device having a vertical structure) formed according to the various aspects of the present disclosure. The vertical LED device 400 contains the various layers and components 40-210 shown in FIG. 5 and discussed above, except that they are shown to be in a vertically “flipped” configuration.

A bonding and barrier metal layer 410 is formed on the reflective layer 210. In an embodiment, the bonding and barrier metal layer 410 contains a barrier metal such as Ti, Pt, W, Ni, Pd, or ITO, and a bonding metal such as Au, Sn, Zn, In, Ag, or ITO. A substrate 450 is bonded to the layers 40-310 of the LED device through the bonding and barrier metal layer 410. The substrate 40 is then removed, as are other layers formed between the substrate 40 and the doped semiconductor layer 60. A metal pad 420 is formed on the exposed surface of the doped semiconductor layer 60. In an embodiment, the metal pad 420 contains Cr, Ti, Al, In, Pd, or ITO. To complete the fabrication of the vertical LED device 300, additional processes such as dicing, packaging, and testing processes may also be performed, but they are not illustrated herein for the sake of simplicity.

During the operation of both the flip-chip LED device 300 and the vertical LED device 400, at least a portion of the light emitted by the MQW layer 70 propagates “downward” toward the nano-scale structures 200 and the reflective layer 210. This light is then reflected back “upward” by the reflective layer 210 (and the nano-scale structures 200 in some embodiments). As discussed above, due to the various advantages offered by the nano-scale structures 200, such as improved adhesion and Ohmic contact properties, the LED devices disclosed herein have better and more efficient performance and longer lifetime.

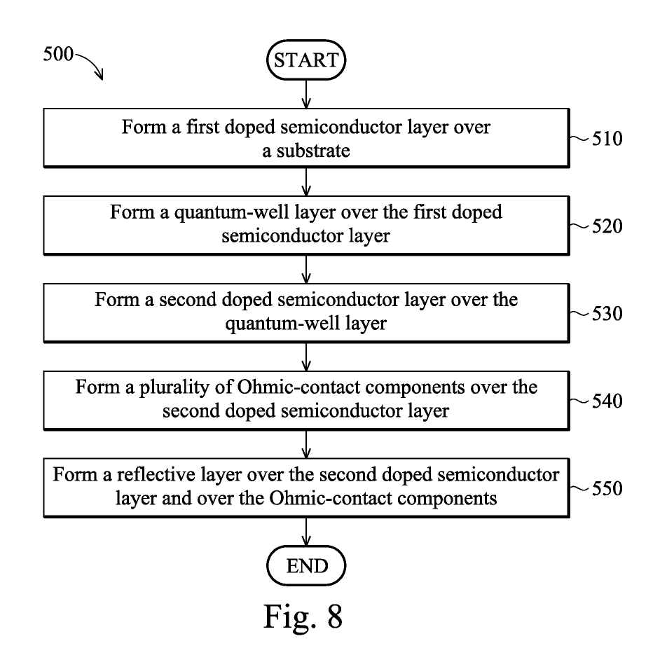

FIG. 8 is a flowchart of a method 500 for fabricating a photonic device according to various aspects of the present disclosure. Referring to FIG. 8, the method 500 includes block 510, in which a first doped semiconductor layer is formed over a substrate. In an embodiment, the first doped semiconductor layer includes a III-V family/group compound, for example gallium nitride. In an embodiment, the substrate includes a sapphire substrate.

The method 500 includes block 520, in which a quantum-well layer is formed over the first doped semiconductor layer. In an embodiment, the quantum-well layer includes a multiple quantum well. The multiple quantum well may include alternating layers of gallium nitride and indium gallium nitride.

The method 500 includes block 530, in which a second doped semiconductor layer is formed over the quantum-well layer. The first and second doped semiconductor layers are oppositely doped. In an embodiment, the second doped semiconductor layer includes a III-V family/group compound, for example gallium nitride.

The method 500 includes block 540, in which a plurality of Ohmic contact components is formed over the second doped semiconductor layer. In an embodiment, the Ohmic contact components each include a material such as: Nickel, Titanium, Aluminum, Platinum, Palladium, Indium, Tin, and alloys thereof. In an embodiment, the Ohmic contact components each have a thickness in a range from about 3 Angstroms to about 20 Angstroms. The Ohmic contact components may be formed using a patterned mask layer. In an embodiment, the Ohmic contact components may have a periodic distribution. In an embodiment, the Ohmic contact components occupy about 0.5% to about 20% of a total chip surface area.

The method 500 includes block 550, in which a reflective layer is formed over the second doped semiconductor layer and over the Ohmic contact components. In an embodiment, the reflective layer includes at least one of: Aluminum, Silver, and alloys thereof. In an embodiment, the reflective layer is at least fifty times thicker than the Ohmic contact components.

It is understood that additional processes may be performed before, during, or after the blocks 510-550 discussed herein to complete the fabrication of the photonic devices.

The foregoing has outlined features of several embodiments so that those skilled in the art may better understand the detailed description that follows. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions and alterations herein without departing from the spirit and scope of the present disclosure.

1. A method of fabricating a photonic device, comprising:
forming a first doped semiconductor layer over a substrate;
forming a quantum-well layer over the first doped semiconductor layer;
forming a second doped semiconductor layer over the quantum-well layer, the first and second doped semiconductor layers being oppositely doped;
forming a patterned mask layer over the second doped semiconductor layer;
forming a conductive layer over the second doped semiconductor layer and over the patterned mask layer; and
removing the patterned mask layer, thereby removing portions of the conductive layer formed directly on the patterned mask layer, wherein a plurality of Ohmic contact components are formed by remaining portions of the conductive layer disposed on the second doped semiconductor layer after the removing the patterned mask layer; and
forming a reflective layer over the second doped semiconductor layer and over the Ohmic contact components.

2. The method of claim 1, wherein the first doped semiconductor layer and the second doped semiconductor layer each include a III-V family material.

3. The method of claim 2, wherein the III-V family material includes gallium nitride.

4. The method of claim 1, wherein the Ohmic contact components each include a material selected from the group consisting of: Nickel, Titanium, Aluminum, Platinum, Palladium, Indium, Tin, and alloys thereof.

5. The method of claim 1, wherein the Ohmic contact components each have a thickness in a range from about 3 Angstroms to about 20 Angstroms.

6. The method of claim 1, wherein one of the first and second doped semiconductor layers is a n-type doped, and the other one of the first and second doped semiconductor layers is p-type doped.

7. The method of claim 1, wherein the Ohmic contact components have a periodic distribution.

8. The method of claim 1, wherein the reflective layer includes one of: Aluminum, Silver, and alloys thereof.

9. The method of claim 1, wherein the Ohmic contact components occupy a percentage of total chip surface area, the percentage being in a range from about 0.5% to about 20%.

10. The method of claim 1, further including:
forming a bonding metal layer over the reflective layer; and
bonding a substrate to the photonic device through the bonding metal layer.

11. A method of fabricating a lighting apparatus, comprising:
forming a first III-V group compound layer over a substrate, wherein the first III-V group compound layer has a first type of conductivity;
forming a multiple quantum well (MQW) layer over the first III-V group compound layer;
forming a second III-V group compound layer over the MQW layer, wherein the second III-V group compound layer has a second type of conductivity different from the first type of conductivity;
forming a plurality of conductive components over the second III-V group compound layer; and
forming a light-reflective layer over the second III-V group compound layer and over the conductive components, wherein at least a portion of the light-reflective layer is formed to be in direct contact with the second III-V group compound layer;
wherein the conductive components each have better adhesive and electrical conduction properties than the light-reflective layer.

12. The method of claim 11, wherein the first III-V group compound layer and the second III-V group compound layer each include a gallium nitride material.

13. The method of claim 11, wherein the conductive components each include at least one of: Nickel, Titanium, Aluminum, Platinum, Palladium, Indium, Tin, and combinations thereof.

14. The method of claim 11, wherein the light-reflective layer includes at least one of: Aluminum, Silver, and alloys thereof.

15. The method of claim 11, wherein:
the conductive components each have a thickness no greater than about 20 Angstroms; and
the reflective layer has a thickness that is greater than about 1000 Angstroms.

16. The method of claim 11, wherein the conductive components are formed at least in part by forming a patterned mask layer having a periodic distribution.

17. A photonic device, comprising:
a first doped semiconductor layer disposed over a substrate;
a quantum-well layer disposed over the first doped semiconductor layer;
a second doped semiconductor layer disposed over the quantum-well layer, the first and second doped semiconductor layers being oppositely doped;
a plurality of conductive nano-scale structures disposed over the second doped semiconductor layer; and
a reflective layer disposed over the second doped semiconductor layer and over the conductive nano-scale structures, wherein at least a portion of the reflective layer is in direct contact with the second doped semiconductor layer;
wherein:
the first doped semiconductor layer and the second doped semiconductor layer each include a III-V family material; and
the nano-scale structures are substantially thinner than the reflective layer.

18. The photonic device of claim 17, wherein the conductive nano-scale structures each include a material selected from the group consisting of: Nickel, Titanium, Aluminum, Platinum, Palladium, Indium, Tin, and alloys thereof.

19. The photonic device of claim 17, wherein the conductive nano-scale structures have a periodic distribution and are about fifty times thinner than the reflective layer.

20. The photonic device of claim 17, wherein the photonic device includes one of: a flip-chip light-emitting diode (LED) structure and a vertical LED structure.
